(19) United States
(12) Patent Application Publication
(10) Pub. No.: US 2007/0236273 A1
(43) Pub. Date: Oct. 11, 2007

(54) Setting a reference voltage for a bus agent

(76) Inventors: Michael R. Hawthorne, Raleigh, NC (US); Mohamad H. Tawil, Cary, NC (US)

Correspondence Address: IBM (RPS-BLF);c/o BIGGERS & OHANIAN, LLP, P.O. BOX 1469, AUSTIN, TX, 78767-1469, US

(21) Appl. No.: 11/398,289

(22) Filed: Apr. 5, 2006

(51) Int. Cl. H03K 17/04

(52) U.S. Cl. 327/376

(57) ABSTRACT

Setting a reference voltage for a bus agent including identifying a present configuration of a bus, the bus including conductive pathways connected to bus agents, the bus agents including computer hardware devices that use the bus for data communications among bus agents, the present configuration of the bus including the identity of the bus, the identities of one or more bus agents presently connected to the bus, and the order in which the bus agents presently are connected to the bus; identifying a reference voltage value for each bus agent; and applying a reference voltage to each bus agents in dependence upon the identified reference voltage value for each bus agent.

### BACKGROUND OF THE INVENTION

1. Field of the Invention

The field of the invention is data processing, or, more specifically, methods, apparatus, and products for setting a reference voltage for a bus agent.

2. Description of Related Art

Buses in computer systems communicate data between bus agents coupled to the buses. As used in this specification, an “agent” or “bus agent” refers to a computer hardware device that uses a bus for data communications. In a typical configuration, a bus includes one or more data lines and a clock signal line. The clock signal line sets the pace for data communications. In a simplified, theoretical system, when a particular agent is receiving data via a bus, at each clock pulse the agent examines the bus data lines. If a data line has a voltage present, the bit received is a 1; if no voltage is present, the bit received is a 0. However, in a real computer system, bus data lines almost always have some voltage present during operation as a result of induced currents, reflection of signals, etc. The amount of this background noise voltage present on each bus varies with the configuration of the bus. To enable bus agents to detect 1s and 0s in this noisy environment, a reference voltage is often used. The reference voltage gives a discrimination point to the bus agent. If the voltage on a data line is less than the reference voltage, the bus agent considers the received signal to be a 0; if the voltage on the reference line is greater than the reference voltage, the bus agent considers the received signal a 1.

To determine a reference voltage for a bus agent, a computer system designer may determine high and low reference voltage values. The high and low reference voltage values are the reference voltage fail points. That is, if the reference voltage were set any higher than the high reference voltage value the bus agent would not be able to correctly identify one or more high voltage states in the data line, so some 1s could be misinterpreted as 0s. If the reference voltage were set any lower than the low reference voltage value, the bus agent would not be able to correctly identify one or more low voltage states in the data line, so some 0s could be misinterpreted as 1s. A reference voltage value for the bus is then selected that is between the high and low reference voltage limits. For low frequency buses, the midpoint between the high and low reference voltage values may be selected. For high frequency buses, a point two-thirds of the way from the low reference voltage limit to the high reference voltage limit is often selected.

Because the amount of background noise on a bus can vary depending on the configuration of the bus, the high and low reference voltage limits also vary with depending on the configuration. Therefore, when more than one configuration of the bus is possible or likely, computer system designers often select a reference voltage for a bus in dependence upon expected configurations of the bus. One method of doing this is to determine high and low reference voltage values for each bus agent for each possible or likely configuration of the bus. Using this method, several sets of high and low reference voltage limits are determined for each bus agent. The computer system designer then selects a default reference voltage value for each bus agent that is expected to allow the bus agent to operate in any of the configurations considered. One concern with this method of selecting a default reference voltage value for a number of potential configurations is that some margin for error may be sacrificed. That is, during operation using a default reference voltage value, some data signals may be misinterpreted as a result of the default reference voltage value being too high or too low for the actual, present configuration of the bus.

### SUMMARY OF THE INVENTION

Methods, apparatus, and products are disclosed for setting a reference voltage for a bus agent that include identifying a present configuration of a bus, where the bus is composed of conductive pathways connected to bus agents, the bus agents are computer hardware devices that use the bus for data communications among bus agents. The present configuration of the bus may include the identity of the bus, the identities of one or more bus agents presently connected to the bus, and the order in which the bus agents presently are connected to the bus; identifying a reference voltage value for each bus agent; and applying a reference voltage to each bus agents in dependence upon the identified reference voltage value for each bus agent.

### BRIEF DESCRIPTION OF THE DRAWINGS

FIG. 1 sets forth a block diagram of automated computing machinery comprising an exemplary computer useful in setting a reference voltage for a bus agent according to embodiments of the present invention.

FIG. 2 sets forth a functional block diagram illustrating an exemplary system for setting a reference voltage for a bus agent according to embodiments of the present invention.

FIG. 3 sets forth a flow chart illustrating an exemplary method for setting a reference voltage for a bus agent according to embodiments of the present invention.

FIG. 4 sets forth a flow chart illustrating a further exemplary method for setting a reference voltage for a bus agent according to embodiments of the present invention.

FIG. 5 sets forth a flow chart illustrating a further exemplary method for setting a reference voltage for a bus agent according to embodiments of the present invention.

### DETAILED DESCRIPTION OF EXEMPLARY EMBODIMENTS

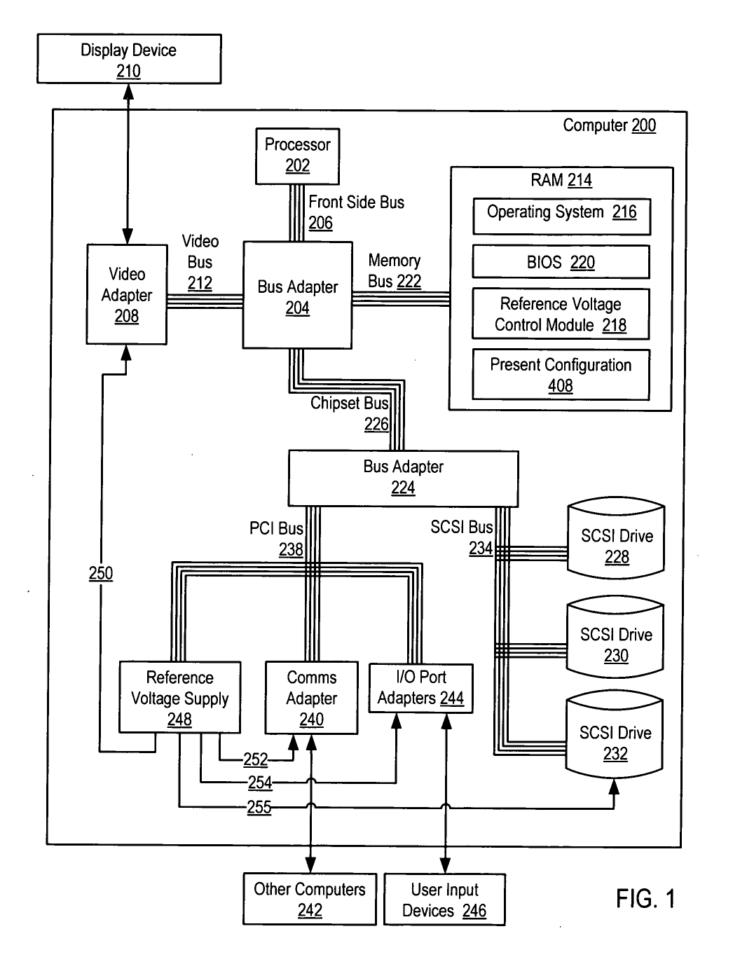

Exemplary methods, apparatus, and products for setting a reference voltage for a bus agent according to embodiments of the present invention are described with reference to the accompanying drawings, beginning with FIG. 1. Setting a reference voltage for a bus agent in accordance with the present invention is generally implemented with computers, that is, with automated computing machinery. FIG. 1 sets forth a block diagram illustrating an exemplary computer system for setting a reference voltage for a bus agent according to embodiments of the present invention. The computer (200) of FIG. 1 operates generally to set a reference voltage for a bus agent according to embodiments of the present invention by identifying a present configuration of a bus; identifying a reference voltage value for each bus agent; and applying a reference voltage to each bus agents in dependence upon the identified reference voltage value for each bus agent.

Computer (200) includes at least one computer processor (202). Processor (202) is coupled to a bus adapter (204) through bus (206). A bus adapter is a computer hardware device that facilitates data communications between other hardware devices on various buses in the computer. A bus adapter facilitates communications between computer components on buses by routing communications to and from bus agents, queuing and scheduling communications to and from bus agents, controlling access to the bus by the bus agents, and acting as an interface between two or more buses. Examples of bus adapters for high speed buses that may be adapted for setting a reference voltage for a bus agent according to embodiments of the present invention include the Intel Northbridge and the Intel Memory Controller Hub.

Bus adapter (204) is coupled to video adapter (208) through bus (212). Video adapter (208) is a computer hardware device that receives video and graphics data, prepares the data for display, and transfers the data to a display device (210). Examples of video adapters useful in systems that set a reference voltage for a bus agent according to embodiments of the present invention include the ATI Radeon™ X1800 GTO Video Card and the Nvidia GeForce™ 7800 GS AGP Video Card. Examples of video buses useful in systems that set a reference voltage for a bus agent according to embodiments of the present invention include the accelerated graphics port (‘AGP’) bus and the peripheral component interconnect express (‘PCI express’) bus.

In computer (200), bus adapter (204) is coupled to random access memory (‘RAM’) (214) though bus (222). Stored in RAM (214) is an operating system (216), a Basic Input Output system (‘BIOS’) (220), a reference voltage control module (218), and a present configuration (408) of a bus. An operating system is a layer of system software that administers system resources and schedules access to those resources. To track system resources, operating system (216) stores the present configuration of the computer, including the present configuration (408) of each bus, in computer memory. Operating systems useful for setting a reference voltage for a bus agent according to embodiments of the present invention include UNIX™, Linux™, Microsoft XP™, AIX™, IBM's i5/OS™, and others as will occur to those of skill in the art. Windows, for example, stores the present configuration in a registry file, and many versions of Unix, AIX, and Linux store the present configuration in disk files in a special files directory, sometimes called a device directory.

BIOS (220) is a set of computer program routines that controls computer hardware devices to implement basic input and output functions of the computer system. BIOS (220) is a lower layer of system software than operating system (216), and routines in the BIOS often are called by the operating system to implement commands to hardware. BIOS (220) stores information about the computer system's present configuration in a memory that the BIOS uses to control the hardware devices. The information about the computer's present configuration stored by the BIOS is less complete than the information stored by the operating system; however, BIOS (220) includes at least sufficient configuration information about the computer to direct the boot up process to a memory where an operating system can be found.

Reference voltage control module (218) is a set of computer software instructions for setting a reference voltage for a bus agent. Reference voltage control module (218) operates generally to set a reference voltage for a bus agent according to embodiments of the present invention by identifying a present configuration of a bus, and identifying a reference voltage value for each bus agent.

Operating system (216), BIOS (220) and reference voltage control module (218) in the example of FIG. 1 are shown in RAM (214). Many components of such software may, however, be stored in non-volatile memory such as SCSI drive (228) or in firmware on a separate memory, such as a BIOS chip, not shown.

Computer (200) of FIG. 1 also includes bus adapter (224) for low speed buses such as I/O buses. Bus adapter (204) and bus adapter (224) form a ‘chipset,’ coupled for data communications through chipset bus (226). Chipset bus (226) is fast enough to supply I/O data to I/O components, but is typically slower than the high speed buses (206, 212, 222) coupled through bus adapter (204). Bus adapter (224) facilitates communications between with slower computer components, typically I/O components, and bus adapter (204). Bus adapter (224) and bus adapter (204) regulate the rate at which data is supplied to and received from faster components, such as the processor (202). This arrangement reduces the amount of time that the faster components spend waiting on the slower components. Examples of bus adapters for low speed buses adaptable for setting a reference voltage for a bus agent in accordance with embodiments of the present invention include the Intel Southbridge and the Intel I/O Controller Hub.

Two I/O buses, PCI bus (238) and SCSI bus (234) are coupled to bus adapter (224). A PCI bus is a type of shared bus where each device on the bus shares the same bus communication lines and a bus master, bus adapter (224) in this case, controls each device's use of the bus. A PCI bus allows relatively easy addition of computer hardware devices via one or more expansion slots. In the example of FIG. 1, input/output port adapters (244), communications adapter (240), and reference voltage supply (248) are coupled to the computer via PCI bus (238).

A SCSI bus is another type of expandable, shared bus. A SCSI bus allows up to eight devices to be attached to the bus, either internal to the computer or external to the computer. In computer (200), three SCSI drives (228, 230, 232) are coupled to SCSI bus (234). SCSI drives (228, 230, 232) are magnetic disk drives, such as hard disk drives, or optical drives, such as CD-ROM drives. Both PCI bus (238) and SCSI bus (234) are examples of buses that may be reconfigured after design and manufacturing leading to a change in the background noise level on the buses, and making setting a new reference voltage for one or more agents on the buses desirable.

Computer (200) also includes a reference voltage supply (248) coupled to bus adapter (224) via PCI bus (238). Reference voltage supply (248) is a computer hardware device adapted in accordance with embodiments of the present invention to apply a reference voltage to one or more bus agent of computer (200) in dependence upon identified reference voltage values for each bus agent. In computer (200), reference voltage supply (248) applies a reference voltage to communications adapter (240) via conductor (252), to input/output port adapters (‘I/O port adapters’) (244) via conductor (254), and to video adapter (250) via conductor (250). The reference voltage provided to each bus agent is dependent upon the reference voltage value identified for that agent by reference voltage control module (218). Reference voltage control module (218) identifies a reference voltage value for each agent in dependence upon the present configuration of the bus to which the agent is coupled. The reference voltage applied to communications adapter (240) and I/O port adapters (244) is determined based on the configuration of PCI bus (238). If the configuration of PCI bus (238) were changed, for example, the position of communications adapter (240) and I/O port adapters (244) were switched, the amount of background noise experienced by the communications adapter (240) and I/O port adapters (244) would likely change. To ensure the proper operation of communications adapter (240) and I/O port adapters (244) after the configuration change, in the example above, reference voltage control module (218) identifies the new present configuration of the PCI bus (238) and identifies a new reference voltage value for communications adapter (240) and I/O port adapters (244). Reference voltage supply then applies a reference voltage to communications adapter (240) and I/O port adapters (244) in dependence upon the identified reference voltage values.

For convenience of explanation, in the system of FIG. 1, reference voltage supply (248) only applies a reference voltage to four bus agents. It will be apparent to those of skill in that art, however, that systems that set a reference voltage for a bus agent according to embodiments of the present invention may apply a reference voltage to any number of bus agents.

Computer (200) also includes I/O port adapters (246). I/O port adapters are computer hardware devices that implement user-oriented input/output for controlling output to devices such as printers, as well as user input from user input devices (246) such as keyboards and mice.

Computer (200) also includes a communications adapter (240) for implementing data communications with other computers (242). Such data communications may be carried out serially through RS-232 connections, through external buses such as USB, through data communications networks such as IP networks, and in other ways as will occur to those of skill in the art. Communications adapters implement the hardware level of data communications through which one computer sends data communications to another computer, directly or through a network. Examples of communications adapters include modems for wired dial-up communications, Ethernet (IEEE 802.3) adapters for wired network communications, and 802.11b adapters for wireless network communications.

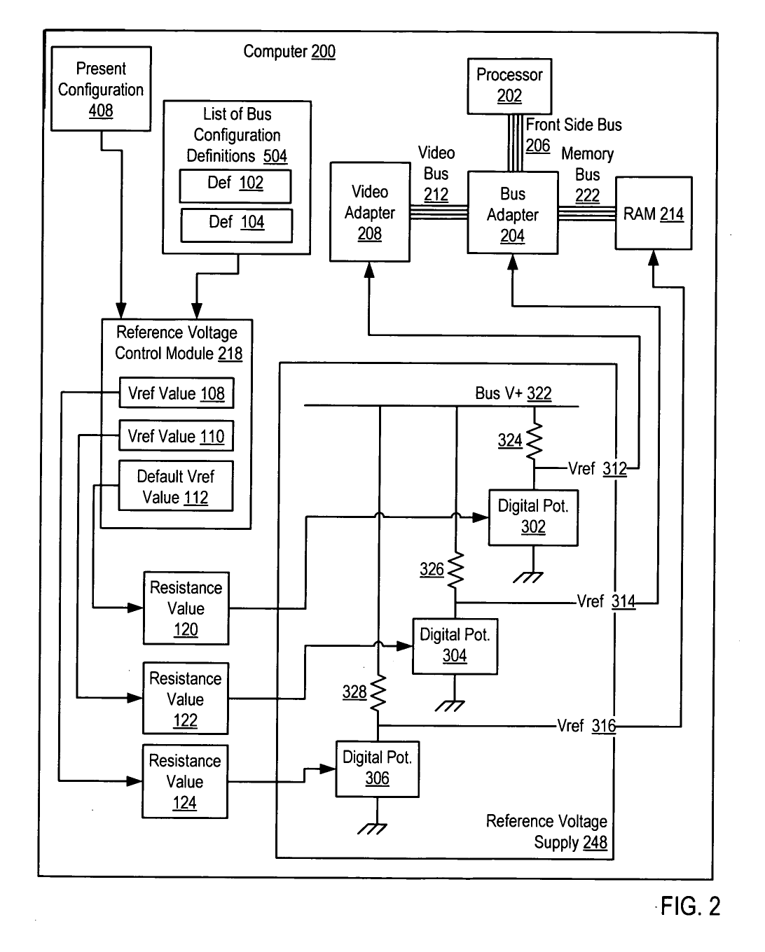

For further explanation, FIG. 2 sets forth a functional block diagram illustrating a further exemplary system for setting a reference voltage for a bus agent according to embodiments of the present invention. The system of FIG. 2 is represented as a computer (200) that includes a processor (202), a video adapter (208), a bus adapter (204), and RAM (214). Processor (202) and bus adapter (204) are bus agents connected to front side bus (206). Video adapter (208) and bus adapter (204) are bus agents on video bus (212). Bus adapter (204) and RAM module (214) are bus agents on memory bus (222). The system of FIG. 2 includes a reference voltage control module (218), a set of computer software instructions for setting a reference voltage for a bus agent. Reference voltage control module (218) operates generally to set a reference voltage for a bus agent according to embodiments of the present invention by identifying a present configuration of a bus and identifying a reference voltage value (108, 110, 112) for each bus agent.

In the system of FIG. 2, reference voltage control module (218) identifies a present configuration of a bus by accessing a present configuration (408) stored in a computer memory. In the system of FIG. 2, present configuration (408) of a bus is the identity of a bus and the identities of agents actually presently connected to the bus and the order in which the agents are connected to the bus. A computer's operating system typically tracks the present configuration of the computer by storing the present configuration of the computer, including the present configuration of each bus, in computer memory.

Reference voltage control module (218) identifies a reference voltage value (108, 110, 112) for each bus agent in the present configuration (408) by accessing a list (504) of bus configuration definitions. Each bus configuration definition (102, 104, 106) in this example is a data structure whose data elements describe a particular set of bus agents that may be connected to a bus, an order in which the agents of the set may be connected, and references voltages for one or more of the agents. Manufacturers of bus agents or other entities having an interest in efficient bus operations typically provide bus configuration definitions for the list of bus configuration definitions. Reference voltage values for the list of bus configuration definitions may also be determined through laboratory measurements of high and low reference voltages limits and selection of suitable reference voltage values based on these measurements.

In the system of FIG. 2, the reference voltage control module (218) identifies a reference voltage value (108, 110, 112) for each bus agent. To identify a reference voltage value (108, 110, 112) for each bus agent, the reference voltage control module (218) selects a bus configuration definition (102, 104, 106) from the list (504) of bus configuration definitions in dependence upon the present configuration (408). The reference voltage control module (218) identifies a reference voltage value (108, 110, 112) for at least one agent in the present configuration in dependence upon the selected bus configuration definition.

The reference voltage control module (218) determines a resistance set point value (120, 122, 124) for each reference voltage value (108, 110, 112). Each resistance set point value (120, 122, 124) is determined in dependence upon the respective identified reference voltage value (108, 110, 112), the bus power supply voltage (‘bus V+’) (322), and the resistance of the respective fixed resistor (324, 326, 328). The resistance set point values (120, 122, 124) are calculated according to:

$$\begin{matrix}Formula 1 \text{:} & \\ {R}_{2} = \frac{{R}_{1} ( {V}_{1} - {V}_{2} )}{{V}_{2}} & \end{matrix}$$

where R₁ is the resistance of the fixed resistor, R₂ is the resistance set point value to be determined, V₁ is the voltage of bus V+, and V₂ is the identified reference voltage value.

In the system of FIG. 2, reference voltage control module (218) sends a resistance set point value (120, 122, 124) to reference voltage supply (248) for each agent in the present configuration (408). A reference voltage supply is a computer hardware component that converts a voltage supplied by the computer system to reference voltages in dependence upon reference voltage values identified for bus agents. In the system of FIG. 2, reference voltage supply (248) converts bus V+ into reference voltages in response to receiving resistance set point values (120, 122, 124) from reference voltage control module (218), which determines the resistance set point values (120, 122, 124) in dependence upon the identified reference voltage values (108, 110, 112). Reference voltage supply (248) applies a reference voltage to each bus agent in the present configuration (408) in dependence upon resistance set point values (120, 122, 124).

In the system of FIG. 2, reference voltage supply (248) includes three reference voltage supply lines (312, 314, 316). A reference voltage supply line is a conductor through which a reference voltage is applied to a bus agent. In the system of FIG. 2, reference voltage supply lines (312, 314, 316) apply reference voltages, set by reference voltage supply (248), to video adapter (208), bus adapter (204), and RAM (214), which are agents of video bus (212), memory bus (214), and front side bus (206).

Reference voltage supply also includes digital potentiometers (302, 304, 306). A digital potentiometer is a variable resistor the resistance of which is adjustable in response to a received resistance set point value. In the system of FIG. 2, digital potentiometers (302, 304, 306) are resistors in a voltage divider circuit. By adjusting the resistance of digital potentiometers (302, 304, 306) the voltage applied to reference voltage supply lines (312, 314, 316) can be adjusted. Digital potentiometers (320, 304, 306) adjust their resistance in response to resistance set point values (120, 122, 124), respectively. Digital potentiometer (302), for example, sets its resistance in response to resistance set point value (120) to adjust the reference voltage applied to reference voltage supply line (312). Digital potentiometers (304, 306) likewise adjust their resistances in response to resistance set point values (122, 124) to set the reference voltages applied to reference voltage supply lines (314, 316), respectively.

For convenience of explanation, in the system of FIG. 2, reference voltage supply (248) includes only three reference voltage supply lines (312, 314, 316). It will be apparent to those of skill in that art, however, that systems that set a reference voltage for a bus agent according to embodiments of the present invention may apply a reference voltage to any number of bus agents, and that a reference voltage supply may include any number of reference voltage supply lines, digital potentiometers and voltage divider circuits.

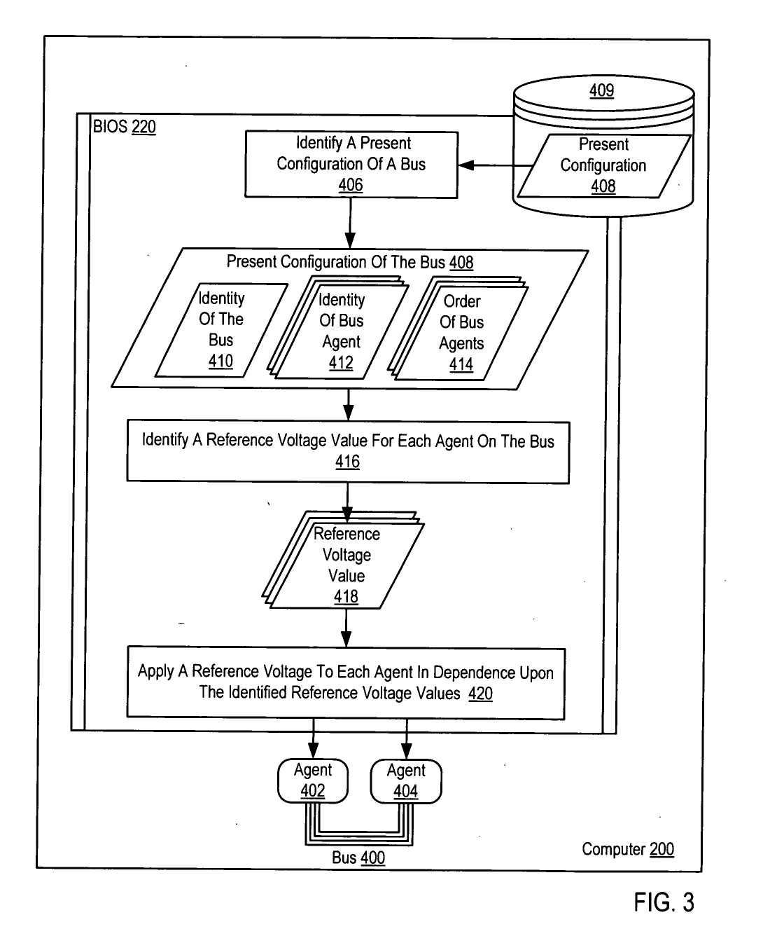

For further explanation, FIG. 3 sets forth a flow chart illustrating an exemplary method for setting a reference voltage for a bus agent according to embodiments of the present invention. The method of FIG. 3 is carried out in a computer (200) having a bus (400) with bus agents (402, 404) connected to the bus. Bus (400) includes conductive pathways connected to bus agents (402, 404). The bus agents (402, 404) are computer hardware devices that use the bus (400) for data communications among bus agents (402, 404).

The method of FIG. 3 includes identifying (406) a present configuration (408) of the bus. The present configuration (408) of the bus includes the identity (410) of the bus, the identities (412) of one or more bus agents presently connected to the bus, and the order (414) in which the bus agents presently are connected to the bus (400). Identifying (406) a present configuration (408) of the bus may be carried out as part of a boot routine in a BIOS or operating system. The boot routine may, for example, identify a present configuration by retrieving the present configuration (408) from non-volatile computer memory. Non-volatile computer memory is represented in the method of FIG. 3 by disk storage (409), although readers will recognize that non-volatile computer memory also may be implemented as Flash memory, NVRAM, or any other non-volatile computer memory that may occur to those of skill in the art. The computer's BIOS or operating system typically maintains a computer's present configuration in computer memory, as, for example, a Windows registry or a Unix/dev file. BIOS (220) uses such a present configuration of the computer to direct the boot process, load drivers and the like, and to control the computer's hardware devices. An operating system of computer (200), such as, for example, the operating system illustrated and described above with regard to reference (214) of FIG. 1, also uses the computer's present configuration to administer access to computer resources.

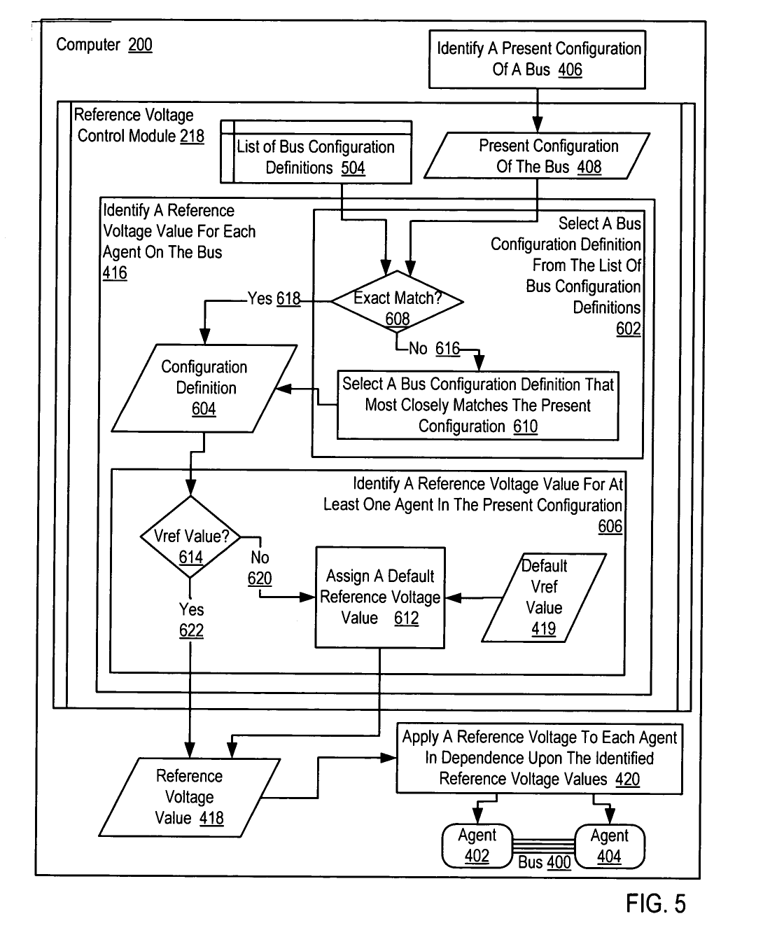

The method of FIG. 3 also includes identifying (416) a reference voltage value (418) for each bus agent (402, 404) on the bus (400). Identifying a reference voltage value (418) for each bus agent (402, 404) on the bus (400) may be carried out by selecting a bus configuration definition from a list of bus configuration definitions, and identifying a reference voltage value for at least one agent in the present configuration in dependence upon the selected bus configuration definition. The discussion of the method of FIG. 5 below includes a more detailed description of an exemplary method of identifying a reference voltage value for each bus agent.

The method of FIG. 3 also includes applying (420) a reference voltage to each bus agent (402, 404) in dependence upon the identified reference voltage value (418) for each bus agent. Applying (420) a reference voltage to each bus agent (402, 404) in dependence upon the identified reference voltage value (418) for each bus agent may be carried out by a reference voltage control module and a reference voltage supply, as shown in FIG. 2. Reference voltage control module (218 on FIG. 2) determines a resistance set point value using Formula 1, as described above in the description of FIG. 2. The reference voltage control module provides the resistance values to digital potentiometers in a reference voltage supply (248 on FIG. 2). The reference voltage supply applies a reference voltage to each bus agent.

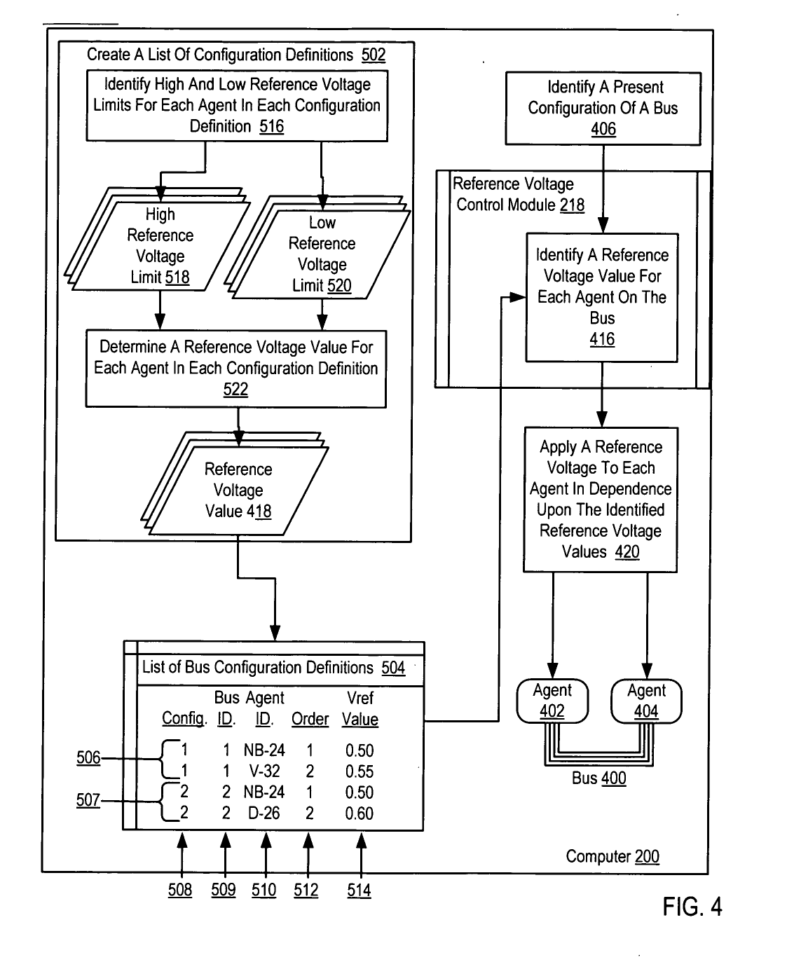

For further explanation, FIG. 4 sets forth a flow chart illustrating a further exemplary method for setting a reference voltage for a bus agent according to embodiments of the present invention. The method of FIG. 4 is carried out in a computer (200) having a bus (400) with bus agents (402, 404) connected to the bus. The method of FIG. 4 is similar to the method of FIG. 3. That is, the method of FIG. 4 includes identifying (406) a present configuration of a bus, identifying a reference voltage value for each agent on the bus, and applying (420) a reference voltage to each agent in dependence upon identified reference voltage values, all of which operate generally as described above with reference to the method of FIG. 3.

The method of FIG. 4 also includes creating (502) a list (504) of bus configuration definitions. The list (504) of bus configuration definitions includes for each bus configuration definition an identifier (509) for a bus, an identifier (510) for each agent to be connected to the identified bus, an order (512) in which the agents are to be connected to the identified bus, and a reference voltage value (514) for each such agent. In the method of FIG. 4, creating a list of configuration definitions (502) includes identifying (516) high reference voltage limits (518) and low reference voltage limits (520) for each agent in each bus configuration definition. High (518) and low (520) reference voltage limits for a bus agent in a particular configuration of a bus described in a bus configuration definition may be identified, for example, by laboratory testing of the bus configuration to determine the range of reference voltage values over which a bus agent in the configuration functions properly. Other methods of identifying high and low reference voltage limits, such as simulation of the bus and one or more bus agents, will be apparent to those of skill in the art, and all such methods are well within the scope of the present invention.

The method of FIG. 4 also includes determining (522) a reference voltage value (418) for each agent in dependence upon the high (518) and low (520) reference voltage limits for each agent. Determining (522) a reference voltage value (418) for an agent may include selecting a reference voltage value at a midpoint between the high (518) and low (520) reference voltage limits of a bus, for relatively low speed buses, for example. For faster buses, determining (522) a reference voltage value (418) for an agent may include selecting a reference voltage value that is two-thirds of the way from the low reference voltage limit to the high reference voltage limit.

Each bus configuration definition (506, 507) in the method of FIG. 4 is a data structure whose data elements identify a particular set of bus agents that may be connected to a bus, an order in which the agents of the set may be connected, and references voltages for one or more of the agents. The list (504) of bus configuration definitions in the example of FIG. 4 is presented as a table in which each record represents a bus agent, and a set of records having the same configuration identifier represents a bus configuration definition. Each record in the list (504) includes a configuration identifier field (508) that provides a storage location for an identification code for a bus configuration. Each record in the list (504) also includes a bus identifier field (509) that provides a storage location for an identification code for a bus. Each record in the list (504) also includes an agent identifier field (510) that provides a storage location for an identification code for a bus agent. Each record in the list (504) also includes an order field (510) that provides a storage location for an identification code for an order of a bus agent connected to the bus. Each record in the list (504) also includes a reference voltage value (‘Vref Value’) field (510) that provides a storage location for a reference voltage value for a bus agent.

In the example of FIG. 4, list (504) of bus configuration definitions includes two bus configurations (506,507), each of which is composed of two records in the list. Each record includes an identifier (509) for a bus, an identifier (510) for each agent to be connected to the identified bus, an order (512) in which the agents are to be connected to the identified bus, and a reference voltage value (514) for each such agent. Bus configuration (506) includes two records representing bus agents, one for bus agent ‘NB-24’ and one for bus agent ‘V-32.’ Bus configuration (506) identifies the order (512) in which the bus agents are connected to the bus in configuration (506): NB-24 in bus position 1, and V-32 in bus position 2. Bus configuration (506) also identifies reference voltage values for the bus agents: 0.50 for NB-24, and 0.55 for V-32. Bus configuration (507) includes two records representing bus agents, one for bus agent ‘NB-24’ and one for bus agent ‘D-26.’ Bus configuration (507) identifies the order (512) in which the bus agents are connected to the bus in configuration (507): NB-24 in bus position 1, and D-26 in bus position 2. Bus configuration (507) also identifies reference voltage values for the bus agents: 0.50 for NB-24 and 0.60 for D-26.

The method of FIG. 5, however, represents a more detailed explanation of identifying (416) a reference voltage value (418) for each agent on the bus. In the method of FIG. 5, identifying (416) a reference voltage value (418) for each agent on the bus includes selecting (602) a bus configuration definition (604) from the list (504) of bus configuration definitions. Selecting (602) a bus configuration definition (604) from the list (504) of bus configuration definitions may be carried out by a reference voltage control module (218), such as the reference voltage control module described at reference (218) on FIG. 2. In the method of FIG. 5, if a bus configuration definition in the list (504) of bus configuration definitions matches (618) the present configuration (408), the reference control module (218) selects the matching bus configuration definition and identifies (606) a reference voltage value for at least one agent in the present configuration (408) by reading one or more reference voltages from the bus configuration definition. If no bus configuration definition in the list (504) of bus configuration definitions exactly matches (616) the present configuration (408), the reference voltage control module (218) selects (610) a bus configuration definition (604) that most closely matches the present configuration (408). The reference voltage control module (218) may select a bus configuration that most closely matches the present configuration, for example, by selecting a bus configuration definition from the list of bus configuration definitions having the largest number of the same bus agents in the same order as present configuration (408). In selecting a bus configuration that most closely matches a present configuration, a reference voltage control module may use fuzzy logic, data mining techniques, statistical methods, and any other process for selecting close matches as may occur to those of skill in the art.

In the method of FIG. 5, identifying (416) a reference voltage value for each agent on the bus also includes identifying (606) a reference voltage value (418) for at least one agent in the present configuration (408) in dependence upon the selected bus configuration definition (604). In this example, identifying a reference voltage value (418) for at least one agent in the present configuration (408) in dependence upon the selected bus configuration definition (604) is carried out by reference voltage control module (218). If the selected bus configuration definition (604) includes (622) a reference voltage value (418) for each agent in the present configuration, the reference voltage control module (218) identifies the reference voltage values from the selected bus configuration definition as the values of the reference voltages to be applied to the bus agents. If the selected bus configuration definition (604) has no reference voltage value (620) for an agent presently connected to the bus, the reference voltage control module (218) assigns (612) a default reference voltage value of the bus (419) as a reference voltage value (418) for an agent whose reference voltage value is not included in the selected bus configuration definition (604). In the example of FIG. 5, the default reference voltage value of the bus (419) is a reference voltage value selected by designer or manufacturer, for example, to work in at least some bus configurations.

### Use Cases

Introduction: The following exemplary use cases are presented for further explanation of identifying a reference voltage value for each agent on a bus. The use cases, as presented, include descriptions of sequences of events and data flows used in this example to set a reference voltage for a bus agent according to embodiments of the present invention.

Use case 1: The present configuration of a bus has been identified and a list of configuration definitions has been provided. A reference voltage control module searches the list of configuration definition for a bus configuration definition that exactly matches the present configuration of the bus. No bus configuration definition in the list of bus configuration definitions exactly matches the present configuration of the bus because in the present configuration of the bus, the bus has four agents, but no bus configuration definition for this particular bus includes more than three agents. The reference voltage control module selects a bus configuration definition that most closely matches the present configuration of the bus. In this use case, selecting a most closely matching bus configuration definition is carried out by selecting a bus configuration definition that includes three agents with the same identities and in the same order as in the present configuration. Because the selected bus configuration definition includes only three bus agents, and the present configuration of the bus includes four bus agents, the selected bus configuration definition does not have a reference voltage value for one agent in the present configuration. The reference voltage control module, therefore, assigns a default reference voltage value for the bus to that agent. The reference voltage control module identifies reference voltage values for the three agents that are in the selected bus configuration definition from the bus configuration definition. The reference voltage control module determines a resistance set point value for each bus agent in accordance with Formula 1 (described above in the discussion of FIG. 2) using the reference voltage values identified by the reference voltage control module, the resistance of fixed resistors of a voltage divider circuit, and bus V+ of a reference voltage supply. The reference voltage control module sends the resistance set point values to the reference voltage supply, and the reference voltage supply applies a reference voltage to each bus agent in the present configuration in dependence upon the resistance set point values.

Use case 2: The present configuration of a bus has been identified and a list of configuration definitions has been provided. A reference voltage control module searches the list of configuration definition for a bus configuration definition that exactly matches the present configuration of the bus. No bus configuration definition in the list of bus configuration definitions exactly matches the present configuration of the bus because no bus configuration definition for the particular bus includes the same four bus agents as the bus present configuration. The reference voltage control module selects a bus configuration definition that most closely matches the present configuration of the bus. In this use case, selecting a most closely matching bus configuration definition is carried out by selecting a bus configuration definition that includes three agents with the same identities and in the same order as in the present configuration. Because no reference voltage value for the mismatched agent presently connected to the bus is included in the bus configuration definition, the reference voltage control module assigns a default reference voltage value of the bus to that agent. The reference voltage control module identifies reference voltage values for the three agents that are in the selected bus configuration definition from the bus configuration definition. The reference voltage control module determines a resistance set point value for each bus agent in accordance with Formula 1 (described above in the discussion of FIG. 2) using the reference voltage values identified by the reference voltage control module, and the resistance of fixed resistors of a voltage divider circuit, and bus V+ of a reference voltage supply. The reference voltage control module sends the resistance set point values to the reference voltage supply, which applies a reference voltage to each bus agent in the present configuration in dependence upon the resistance set point values.

Use case 3: The present configuration of a bus has been identified and a list of configuration definitions has been provided. A reference voltage control module searches the list of configuration definition for a bus configuration definition that exactly matches the present configuration of the bus. No bus configuration definition in the list of bus configuration definitions exactly matches the present configuration of the bus because no bus configuration definition for the particular bus includes the same four bus agents as the bus present configuration. The reference voltage control module selects a bus configuration definition that most closely matches the present configuration of the bus. In this use case, selecting a most closely matching bus configuration definition is carried out by selecting a bus configuration definition that includes three agents with the same identities and in the same order as in the present configuration. Because no reference voltage value for the mismatched agent presently connected to the bus is included in the bus configuration definition, the reference voltage control module assigns the reference voltage value for the mismatched fourth agent in the selected bus configuration definition to the fourth agent in the present configuration. The reference voltage control module identifies reference voltage values for the three agents that are in the selected bus configuration definition from the bus configuration definition. The reference voltage control module determines a resistance set point value for each bus agent in accordance with Formula 1 (described above in the discussion of FIG. 2) using the reference voltage values identified by the reference voltage control module, and the resistance of fixed resistors of a voltage divider circuit, and bus V+ of a reference voltage supply. The reference voltage control module sends the resistance set point values to the reference voltage supply, which applies a reference voltage to each bus agent in the present configuration in dependence upon the resistance set point values.

Exemplary embodiments of the present invention are described largely in the context of a fully functional computer system for setting a reference voltage for a bus agent. Readers of skill in the art will recognize, however, that the present invention also may be embodied in a computer program product disposed on signal bearing media for use with any suitable data processing system. Such signal bearing media may be transmission media or recordable media for machine-readable information, including magnetic media, optical media, or other suitable media. Examples of recordable media include magnetic disks in hard drives or diskettes, compact disks for optical drives, magnetic tape, and others as will occur to those of skill in the art. Examples of transmission media include telephone networks for voice communications and digital data communications networks such as, for example, Ethernets™ and networks that communicate with the Internet Protocol and the World Wide Web. Persons skilled in the art will immediately recognize that any computer system having suitable programming means will be capable of executing the steps of the method of the invention as embodied in a program product. Persons skilled in the art will recognize immediately that, although some of the exemplary embodiments described in this specification are oriented to software installed and executing on computer hardware, nevertheless, alternative embodiments implemented as firmware or as hardware are well within the scope of the present invention.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A method for setting a reference voltage for a bus agent, the method comprising:
identifying a present configuration of a bus, the bus comprising conductive pathways connected to bus agents, the bus agents comprising computer hardware devices that use the bus for data communications among bus agents, the present configuration of the bus comprising the identity of the bus, the identities of one or more bus agents presently connected to the bus, and the order in which the bus agents presently are connected to the bus;
identifying a reference voltage value for each bus agent; and
applying a reference voltage to each bus agents in dependence upon the identified reference voltage value for each bus agent.

2. The method of claim 1 further comprising creating a list of bus configuration definitions, each bus configuration definition including an identifier for a bus, an identifier for each agent to be connected to the identified bus, an order in which the agents are to be connected to the identified bus, and a reference voltage value for each such agent.

3. The method of claim 2 wherein creating a list of bus configuration definitions further comprises:
identifying high and low reference voltage limits for each agent in each bus configuration definition; and
determining the reference voltage value for each agent in dependence upon the high and low reference voltage limits for each agent.

4. The method of claim 2 wherein identifying a reference voltage value for each agent further comprises:
selecting a bus configuration definition from the list of bus configuration definitions in dependence upon the identity of the bus, the identities of one or more bus agents presently connected to the bus, and the order in which the bus agents presently are connected to the bus; and
identifying a reference voltage value for at least one agent in the present configuration in dependence upon the selected bus configuration definition.

5. The method of claim 4 wherein:
no bus configuration definition in the list of bus configuration definitions exactly matches the present configuration, and
selecting a bus configuration definition from a list of bus configuration definitions further comprises selecting a bus configuration definition that most closely matches the present configuration.

6. The method of claim 5 wherein:
the selected bus configuration definition contains no reference voltage value for at least one agent presently connected to the bus, and
identifying a reference voltage value for at least one agent in the present configuration in dependence upon the selected bus configuration definition further comprises assigning a default reference voltage value of the bus as a reference voltage value for an agent whose reference voltage value is not included in the selected bus configuration definition.

7. An apparatus for setting a reference voltage for a bus agent, the apparatus comprising a computer processor, a computer memory operatively coupled to the computer processor, the computer memory having disposed within it computer program instructions capable of:
identifying a present configuration of a bus, the bus comprising conductive pathways connected to bus agents, the bus agents comprising computer hardware devices that use the bus for data communications among bus agents, the present configuration of the bus comprising the identity of the bus, the identities of one or more bus agents presently connected to the bus, and the order in which the bus agents presently are connected to the bus; and
identifying a reference voltage value for each bus agent;
the apparatus further comprising means for applying a reference voltage to each bus agents in dependence upon the identified reference voltage value for each bus agent.

8. The apparatus of claim 7 further comprising computer program instructions capable of:
creating a list of bus configuration definitions, each bus configuration definition including an identifier for a bus, an identifier for each agent to be connected to the identified bus, an order in which the agents are to be connected to the identified bus, and a reference voltage value for each such agent.

9. The apparatus of claim 8 wherein creating a list of bus configuration definitions further comprises:
identifying high and low reference voltage limits for each agent in each bus configuration definition; and
determining the reference voltage value for each agent in dependence upon the high and low reference voltage limits for each agent.

10. The apparatus of claim 8 wherein identifying a reference voltage value for each agent further comprises:
selecting a bus configuration definition from the list of bus configuration definitions in dependence upon the identity of the bus, the identities of one or more bus agents presently connected to the bus, and the order in which the bus agents presently are connected to the bus; and
identifying a reference voltage value for at least one agent in the present configuration in dependence upon the selected bus configuration definition.

11. The apparatus of claim 10 wherein:
no bus configuration definition in the list of bus configuration definitions exactly matches the present configuration, and
selecting a bus configuration definition from a list of bus configuration definitions further comprises selecting a bus configuration definition that most closely matches the present configuration.

12. The apparatus of claim 11 wherein:
the selected bus configuration definition contains no reference voltage value for at least one agent presently connected to the bus, and
identifying a reference voltage value for at least one agent in the present configuration in dependence upon the selected bus configuration definition further comprises assigning a default reference voltage value of the bus as a reference voltage value for an agent whose reference voltage value is not included in the selected bus configuration definition.

13. A computer program product for setting a reference voltage for a bus agent, the computer program product disposed upon a signal bearing medium, the computer program product comprising computer program instructions capable of:
identifying a present configuration of a bus, the bus comprising conductive pathways connected to bus agents, the bus agents comprising computer hardware devices that use the bus for data communications among bus agents, the present configuration of the bus comprising the identity of the bus, the identities of one or more bus agents presently connected to the bus, and the order in which the bus agents presently are connected to the bus;
identifying a reference voltage value for each bus agent; and
applying a reference voltage to each bus agents in dependence upon the identified reference voltage value for each bus agent.

14. The computer program product of claim 13 wherein the signal bearing medium comprises a recordable medium.

15. The computer program product of claim 13 wherein the signal bearing medium comprises a transmission medium.

16. The computer program product of claim 13 further comprising computer program instructions capable of:
creating a list of bus configuration definitions, each bus configuration definition including an identifier for a bus, an identifier for each agent to be connected to the identified bus, an order in which the agents are to be connected to the identified bus, and a reference voltage value for each such agent.

17. The computer program product of claim 16 wherein creating a list of bus configuration definitions further comprises:
identifying high and low reference voltage limits for each agent in each bus configuration definition; and
determining the reference voltage value for each agent in dependence upon the high and low reference voltage limits for each agent.

18. The computer program product of claim 16 wherein identifying a reference voltage value for each agent further comprises:
selecting a bus configuration definition from the list of bus configuration definitions in dependence upon the identity of the bus, the identities of one or more bus agents presently connected to the bus, and the order in which the bus agents presently are connected to the bus; and
identifying a reference voltage value for at least one agent in the present configuration in dependence upon the selected bus configuration definition.

19. The computer program product of claim 18 wherein:
no bus configuration definition in the list of bus configuration definitions exactly matches the present configuration, and
selecting a bus configuration definition from a list of bus configuration definitions further comprises selecting a bus configuration definition that most closely matches the present configuration.

20. The computer program product of claim 19 wherein:
the selected bus configuration definition contains no reference voltage value for at least one agent presently connected to the bus, and
identifying a reference voltage value for at least one agent in the present configuration in dependence upon the selected bus configuration definition further comprises assigning a default reference voltage value of the bus as a reference voltage value for an agent whose reference voltage value is not included in the selected bus configuration definition.
